(19) United States
(12) Patent Application Publication
(10) Pub. No.: US 2025/0287739 A1
(43) Pub. Date: Sep. 11, 2025

(54) LIGHT EMITTING DEVICE, DISPLAY APPARATUS INCLUDING THE SAME, AND METHOD OF MANUFACTURING LIGHT EMITTING DEVICE

(71) Applicant: SAMSUNG ELECTRONICS CO., LTD., Suwon-si (KR)

(72) Inventors: Junghun PARK, Suwon-si (KR); Junhee CHOI, Suwon-si (KR); Joohun HAN, Suwon-si (KR)

(73) Assignee: SAMSUNG ELECTRONICS CO., LTD., Suwon-si (KR)

(21) Appl. No.: 19/017,128

(22) Filed: Jan. 10, 2025

(30) Foreign Application Priority Data
Mar. 8, 2024 (KR) 10-2024-0033326

(51) Int. Cl. H10H 20/841; H10H 20/01; H10H 20/82; H10H 20/831; H10H 20/833; H10H 29/49

(52) U.S. Cl. CPC H10H 20/841; H10H 20/032; H10H 20/034; H10H 20/82; H10H 20/8312; H10H 20/833; H10H 29/49

(57) ABSTRACT

The light emitting device includes a light emitting portion and an electrode portion each including an epi structure and separated from each other by a trench. The epi structure includes a first conductive semiconductor layer, an active layer, and a second conductive semiconductor layer which are sequentially stacked. A first contact layer and a second contact layer are respectively on the second conductive semiconductor layers of the light emitting portion and the electrode portion. A passivation layer is provided on side surfaces of the light emitting portion and the electrode portion, and the first contact layer and the second contact layer. An opening exposing the first contact layer of the light emitting portion is formed in the passivation layer. A conductive reflective layer is provided on the passivation layer and contacts the first contact layer of the light emitting portion through the opening. A plurality of pores are provided in the first conductive semiconductor layer.

### CROSS-REFERENCE TO RELATED APPLICATION

This application is based on and claims priority under 35 U.S.C. § 119 to Korean Patent Application No. 10-2024-0033326, filed on Mar. 8, 2024, in the Korean Intellectual Property Office, the disclosure of which is incorporated by reference herein in its entirety.

### BACKGROUND

### 1. Field

The disclosure relates to a light emitting device, a display apparatus including the light emitting device, and a method of manufacturing the light emitting device.

### 2. Description of the Related Art

Light emitting diodes (LEDs) are known as the next-generation light sources due to their advantages, such as long lifespan, low power consumption, fast response speed, and environmental friendliness, compared to related art light sources. Because of such advantages, the industrial demand for LEDs is increasing. LEDs have been generally applied and used in various products, such as lighting devices and backlights of display apparatuses.

Recently, micro units or nano units of micro LEDs using group II-VI or group III-V compound semiconductors have been developed. In addition, micro LED displays including micro LEDs directly used as light emitting devices of display pixels have been developed. However, when LEDs are miniaturized to micro or nano units as described above, the luminous efficiency of the LEDs may be reduced.

### SUMMARY

Provided are a light emitting device with improved luminous efficiency, a method of manufacturing the light emitting device, and a display apparatus including the light emitting device.

Additional aspects will be set forth in part in the description which follows and, in part, will be apparent from the description, or may be learned by practice of the presented embodiments of the disclosure. According to an aspect of the disclosure, there is provided a light emitting device including: a light emitting portion and an electrode portion, each of the light emitting portion and the electrode portion including: an epi structure including: a first conductive semiconductor layer including a plurality of pores, an active layer, and a second conductive semiconductor layer, a trench between the light emitting portion, and the electrode portion to expose the first conductive semiconductor layer; a first contact layer on the second conductive semiconductor layer of the light emitting portion; a second contact layer on the second conductive semiconductor layer of the electrode portion; a passivation layer provided on one or more side surfaces of the light emitting portion, and the electrode portion, and on the first contact layer and the second contact layer, the passivation layer including an opening exposing the first contact layer of the light emitting portion; and a conductive reflective layer provided on the passivation layer and contacting the first contact layer of the light emitting portion through the opening.

The plurality of pores may be spaced apart from the active layer by at least 100 nm.

The light emitting device of may further include an electrode pad provided on the conductive reflective layer at a position corresponding to the electrode portion.

The second contact layer may include Indium Tin Oxide (ITO).

A via hole penetrating the epi structure may be formed on the electrode portion to expose the second contact layer.

The via hole may penetrate the second contact layer and the passivation layer to expose the conductive reflective layer.

The light emitting device may further include an electrode pad provided on a surface of the first conductive semiconductor layer opposite to the active layer.

The light emitting device may further include a transmission conductive layer provided on a surface of the first conductive semiconductor layer opposite to the active layer.

The transmission conductive layer may include Indium Tin Oxide (ITO).

The light emitting device may further include a scattering pattern provided on a surface of the first conductive semiconductor layer opposite to the active layer.

According to another aspect of the disclosure, there is provided a method of manufacturing a light emitting device, the method including: forming an epi structure including a first conductive semiconductor layer, an active layer, and a second conductive semiconductor layer on a growth substrate; separating a light emitting portion and an electrode portion from each other by forming a trench in the epi structure to expose the first conductive semiconductor layer; forming a first contact layer on the second conductive semiconductor layer of the light emitting portion, and forming a second contact layer on the second conductive semiconductor layer of the electrode portion; forming a plurality of pores in the first conductive semiconductor layer; forming a passivation layer on one or more side surfaces of the light emitting portion and the electrode portion, and on the first contact layer and the second contact layer; forming an opening in the passivation layer to expose the first contact layer of the light emitting portion; and forming a conductive reflective layer covering the passivation layer and contacting the first contact layer of the light emitting portion through the opening.

The plurality of pores may be spaced apart from the active layer by at least 100 nm.

The method may further include forming an electrode pad on the conductive reflective layer at a position corresponding to the electrode portion.

The first contact layer and the second contact layer each may include Indium Tin Oxide (ITO).

The method may further include transferring the epi structure onto a carrier substrate; and forming a via hole penetrating the first conductive semiconductor layer, the active layer, and the second conductive semiconductor layer of the electrode portion by using the second contact layer as an etch stop layer.

The via hole may penetrate the second contact layer and the passivation layer to expose the conductive reflective layer.

The method may further include transferring the epi structure onto a carrier substrate; and forming an electrode pad on a surface of the first conductive semiconductor layer.

The method may further include forming a scattering pattern on the surface of the first conductive semiconductor layer.

The method may further include forming a transmission conductive layer on the surface of the first conductive semiconductor layer.

According to another aspect of the disclosure, there is provided a display apparatus including: a display panel including a plurality of light emitting devices, and a driving circuit configured to switch the plurality of light emitting devices on or off; and a controller configured to input switching signals of the plurality of light emitting devices to the driving circuit according to an image signal, wherein each of the plurality of light emitting devices includes: a light emitting portion and an electrode portion, each of the light emitting portion and the electrode portion including: an epi structure including: a first conductive semiconductor layer including a plurality of pores, an active layer, and a second conductive semiconductor layer, a trench between the light emitting portion, and the electrode portion; a first contact layer on the second conductive semiconductor layer of the light emitting portion; a second contact layer on the second conductive semiconductor layer of the electrode portion; a passivation layer provided on one or more side surfaces of the light emitting portion, and the electrode portion, and on the first contact layer and the second contact layer, the passivation layer including an opening exposing the first contact layer of the light emitting portion; and a conductive reflective layer provided on the passivation layer and contacting the first contact layer of the light emitting portion through the opening.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a schematic cross-sectional view of a structure of a light emitting device according to an embodiment;

FIG. 2 is a graph showing a result of simulating photoluminescence (PL) characteristics of a light emitting device;

FIG. 3 is a schematic cross-sectional view of a light emitting device according to an embodiment;

FIG. 4 is a schematic cross-sectional view of a light emitting device according to an embodiment;

FIG. 5 is a schematic cross-sectional view of a light emitting device according to an embodiment;

FIG. 6 is a schematic cross-sectional view of a light emitting device according to an embodiment;

FIG. 7 is a schematic cross-sectional view of a light emitting device according to an embodiment;

FIGS. 8A to 8I are diagrams showing a method of manufacturing a light emitting device according to an embodiment;

FIGS. 9A and 9B are diagrams showing an operation of forming a scattering pattern, as an embodiment of a method of manufacturing a light emitting device;

FIG. 10 is a schematic diagram of a display apparatus according to an embodiment;

FIG. 11 is a block diagram of an electronic device including a display according to an embodiment;

FIG. 12 illustrates an embodiment of a mobile device as an application example of an electronic device;

FIG. 13 illustrates an embodiment of a vehicle head-up display apparatus as an application example of an electronic device;

FIG. 14 illustrates an embodiment of augmented reality glasses or virtual reality glasses as an application example of an electronic device;

FIG. 15 illustrates an embodiment of a signage as an application example of an electronic device; and

FIG. 16 illustrates an embodiment of a wearable display as an application example of an electronic device.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a display apparatus and a method of manufacturing the display apparatus will be described in detail with reference to the accompanying drawings. In the following drawings, the same reference numerals refer to the same components, and the size of each component in the drawings may be exaggerated for clarity and convenience of description. The embodiments described below are merely exemplary, and various modifications are possible from these embodiments.

In the following description, when a component is referred to as being “above” or “on” another component, it may be directly above or on the other component while making contact with the other component or may be above or on the other component without making contact with the other component. The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural. When there is no explicit description of the order of operations constituting a method or no contrary description thereto, these operations may be performed in an appropriate order, and are not limited to the order described.

The connecting lines, or connectors shown in the various figures presented are intended to represent functional relationships and/or physical or logical couplings between the various elements. It should be noted that many alternative or additional functional relationships, physical connections or logical connections may be present in a practical device.

The use of all illustrative terms is merely for describing technical ideas in detail, and the scope is not limited by these examples or illustrative terms unless limited by the claims.

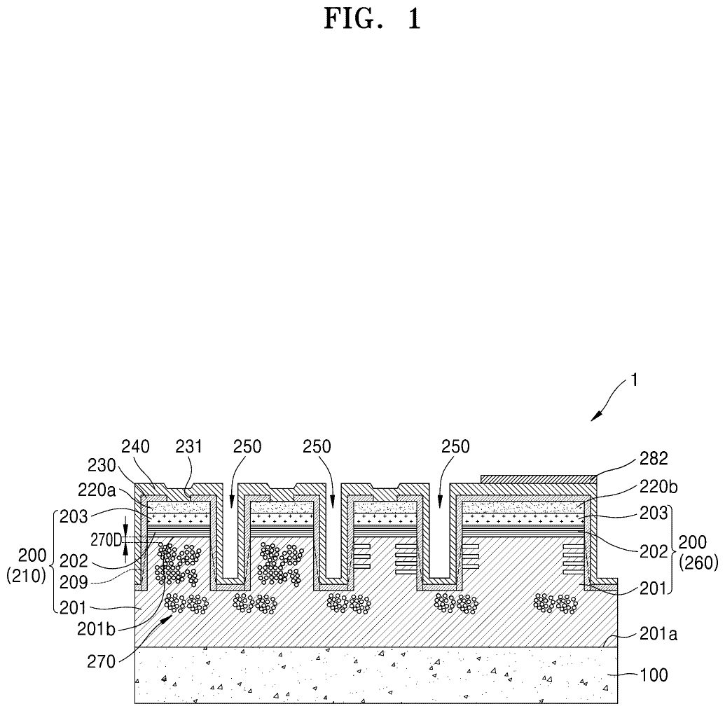

FIG. 1 is a schematic cross-sectional view of a structure of a light emitting device 1 according to an embodiment. The light emitting device 1 of the embodiment is a flip-chip type light emitting device. However, the disclosure is not limited thereto, and as such, the light emitting device 1 may be of a different type. In FIG. 1, for convenience, the light emitting device 1 before being flipped is shown.

Referring to FIG. 1, the light emitting device 1 may include a light emitting portion 210 and an electrode portion 260. The light emitting portion 210 and the electrode portion 260 may each include an epi structure 200. The epi structure 200 may include a first conductive semiconductor layer 201, an active layer 202, and a second conductive semiconductor layer 203. For example, the first conductive semiconductor layer 201, the active layer 202, and the second conductive semiconductor layer 203 are sequentially stacked. The light emitting portion 210 and the electrode portion 260 are separated from each other by a trench 250. A first contact layer 220a and a second contact layer 220b may be provided on the second conductive semiconductor layers 203 of the light emitting portion 210 and the electrode portion 260, respectively. For example, in the light emitting portion 210, the first contact layer 220a may be provided on the second conductive semiconductor layers 203 of the light emitting portion 210, and in the electrode portion 260, the second contact layer 220b may be provided on the second conductive semiconductor layers 203 of the electrode portion 260. A passivation layer 230 may be provided on one or side surfaces of the light emitting portion 210 and the electrode portion 260, and the first contact layer 220a and the second contact layer 220b. For example, the passivation layer 230 may cover the side surfaces of the light emitting portion 210 and the electrode portion 260, and the first contact layer 220a and the second contact layer 220b. An opening 231 is provided in the passivation layer 230 to expose the first contact layer 220a of the light emitting portion 210. According to an embodiment, the conductive reflective layer 240 may be provided on the passivation layer 230. For example, the conductive reflective layer 240 may cover the passivation layer 230. The conductive reflective layer 240 contacts the first contact layer 220a of the light emitting portion 210 through the opening 231. A plurality of pores 270 may be provided in the first conductive semiconductor layer 201.

The light emitting portion 210 may be referred to as a nanorod light emitting portion. The light emitting device 1 may include a plurality of light emitting portions 210 in the form of nanorods. The plurality of light emitting portions 210 are separated from each other by the trenches 250. The electrode portion 260 may entirely correspond to the plurality of light emitting portions 210. The light emitting device 1 may correspond to one pixel or sub-pixel in a display apparatus.

For example, the epi structure 200 may be formed on a substrate 100. The substrate 100 may be referred to as a growth substrate. The substrate 100 is, for example, a growth substrate for semiconductor single crystal growth, and may use a silicon (Si) substrate, a silicon carbide (SiC) substrate, a sapphire substrate, etc. Besides the above, a substrate including a material, suitable for the growth of the epi structure 200 to be formed on the substrate 100, for example, AlN, AlGaN, ZnO, GaAs, MgAl₂O₄, MgO, LiAlO₂, LiGaO₂, GaN, may be used. According to an apparatus to which the light emitting device 1 is applied, the substrate 100 may be removed after completely manufacturing the light emitting device 1. According to an embodiment, a buffer layer for epitaxial growth of the epi structure 200 may be provided on a surface of the substrate 100, and the epi structure 200 may be grown on the buffer layer.

The epi structure 200 may include a Group III-V nitride semiconductor material. The Group III-V nitride semiconductor material may include, for example, GaN, InGaN, AlInGaN, AlGaInP, etc. For example, the epi structure 200 may include a GaN-based semiconductor material. The epi structure 200 has a structure in which the first conductive semiconductor layer 201, the active layer 202 having a quantum well structure, and the second conductive semiconductor layer 203 are sequentially stacked.

The first conductive semiconductor layer 201 may be formed on the substrate 100 by growing in a direction perpendicular to the surface of the substrate 100. The first conductive semiconductor layer 201 may be a semiconductor layer doped with first type impurities. For example, the first conductive semiconductor layer 201 may be an n-GaN layer doped with n-type impurities. Si, Ge, Se, Te, etc. may be used as n-type impurities.

The active layer 202 is a layer that emits light through electron-hole recombination. The active layer 202 may be formed by growing on the first conductive semiconductor layer 201. The active layer 202 has the quantum well structure. For example, the active layer 202 may have a single quantum well structure or a multi quantum well structure obtained by periodically changing x, y, and z values in AlₓGa_{y}In_{z} and adjusting a band gap. For example, a quantum well layer and a barrier layer may be paired in the form of InGaN/GaN, InGaN/InGaN, InGaN/AlGaN, or InGaN/InAlGaN to form the quantum well structure, and a band gap energy may be controlled according to a composition ratio of indium (In) in a material layer including indium (In), and an emission wavelength band may be adjusted.

The second conductive semiconductor layer 203 may be formed on the active layer 202. The second conductive semiconductor layer 203 may be formed by growing on the active layer 202. The second conductive semiconductor layer 203 may be a semiconductor layer doped with second type impurities. For example, the second conductive semiconductor layer 203 may be a p-GaN layer doped with p-type impurities. Mg, Zn, Be, etc. may be used as p-type impurities.

The epi structure 200 may be formed using hybrid vapor phase epitaxy (HVPE), molecular beam epitaxy (MBE), metal organic vapor phase epitaxy (MOVPE), metal organic chemical vapor deposition (MOCVD), etc.

The light emitting portion 210 and the electrode portion 260 are separated from each other by the trench 250 formed by immersing in the epi structure 200. The trench 250 is formed by passing through the second conductive semiconductor layer 203 and the active layer 202 and immersing to the first conductive semiconductor layer 201. The trench 250 is formed by immersing in an arbitrary position between two surfaces of the first conductive semiconductor layer 201. The light emitting portion 210 and the electrode portion 260 share the first conductive semiconductor layer 201.

In FIG. 1, the side surfaces of the light emitting portion 210 and the electrode portion 260 are shown perpendicular to the substrate 100, but the disclosure is not limited thereto. As shown by a dashed line 209 in FIG. 1, the side surfaces of the light emitting portion 210 and the electrode portion 260 may have a tapered shape with respect to the substrate 100. For example, the first conductive semiconductor layer 201 may have the tapered shape from a surface 201b on the active layer 202 toward a surface 201a opposite to the active layer 202. This is due to the difference in an etch rate between near the surface 201b of the first conductive semiconductor layer 201 close to an etch mask in a process of etching the epi structure 200 and near the surface 201a of the first conductive semiconductor layer 201. A width of the first conductive semiconductor layer 201 may gradually increase from the surface 201b to the surface 201a. In other words, a width of the trench 250 may gradually decrease from the surface 201b toward the surface 201a.

The first contact layer 220a is formed on the second conductive semiconductor layer 203 of the light emitting portion 210. The first contact layer 220a forms an ohmic contact with the second conductive semiconductor layer 203. The first contact layer 220a may include a conductive material. The conductive material may include Al, Ti, Pt, Ag, Au, Pd, TiW, or various combinations thereof. The first contact layer 220a may include a transparent conductive material. The transparent conductive material may include ITO (Indium Tin Oxide). The second contact layer 220b is formed on the second conductive semiconductor layer 203 of the electrode portion 260. The second contact layer 220b may include a conductive material. The conductive material may include Al, Ti, Pt, Ag, Au, Pd, TiW, or various combinations thereof. The second contact layer 220b may include a transparent conductive material. The transparent conductive material may include ITO.

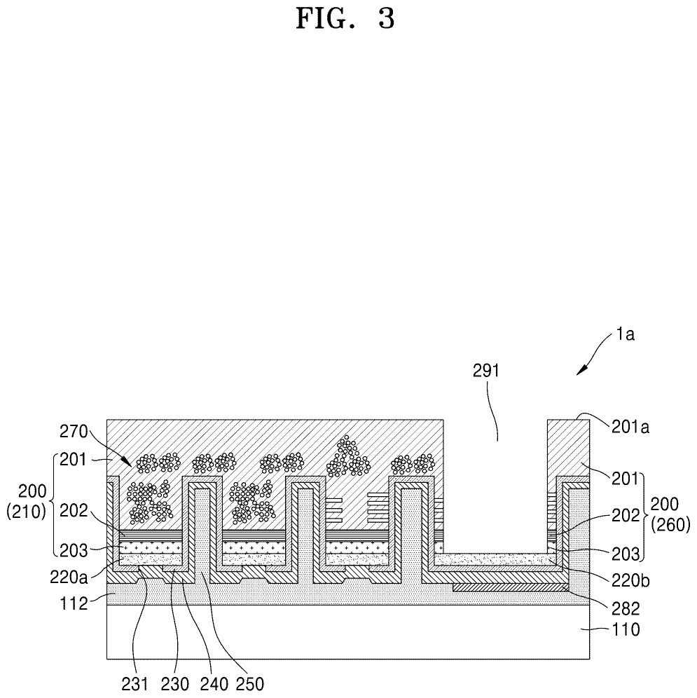

According to an embodiment, the second contact layer 220b may include a material that may function as an etch stop layer with respect to a semiconductor material forming the epi structure 200, for example, GaN. The second contact layer 220b may include, for example, a material having a lower etch rate than that of GaN in an etching process. For example, the second contact layer 220b may include ITO. According to experiments, the etch rate of GaN is about 8.2 nm/s, which is about 19.5 times the etch rate of ITO, which is about 0.42 nm/s. Mathematically, an ITO layer with a thickness of about 100 nm may correspond to a GaN layer with a thickness of about 2 μm in terms of etch thickness, and the second contact layer 220b including ITO may function as an excellent etch stop layer. Accordingly, as is described below, in an example case in which the light emitting device 1 is flipped and used, damage to the conductive reflective layer 240 may be prevented in a process of etching GaN to form a via hole (FIG. 3:291) exposing the conductive reflective layer 240, which is a p-electrode, to the electrode portion 260.

According to an embodiment, the first contact layer 220a and the second contact layer 220b may include the same material. For example, the first contact layer 220a and the second contact layer 220b may include ITO. According to such a configuration, the first contact layer 220a and the second contact layer 220b may be formed through a single process, and thus, a manufacturing process of the light emitting device 1 may be simplified.

According to an embodiment, the passivation layer 230 may be provided on the side surfaces of the light emitting portion 210 and the electrode portion 260. The passivation layer 230 may be provided on the first contact layer 220a and the second contact layer 220b. The passivation layer 230 may be provided on the side surfaces of the first conductive semiconductor layer 201, the active layer 202, and the second conductive semiconductor layer 203 exposed by the trench 250, an upper surface of the first conductive semiconductor layer 201 exposed by the trench 250, and the side surfaces and upper surfaces of the first contact layer 220a and the second contact layer 220b. For example, the passivation layer 230 covers the side surfaces of the light emitting portion 210 and the electrode portion 260. The passivation layer 230 covers the first contact layer 220a and the second contact layer 220b. The passivation layer 230 covers the side surfaces of the first conductive semiconductor layer 201, the active layer 202, and the second conductive semiconductor layer 203 exposed by the trench 250, an upper surface of the first conductive semiconductor layer 201 exposed by the trench 250, and the side surfaces and upper surfaces of the first contact layer 220a and the second contact layer 220b. The passivation layer 230 may protect the light emitting portion 210 from external physical and chemical impacts. The passivation layer 230 may prevent current leakage by insulating the light emitting portion 210. The opening 231 is provided in the passivation layer 230. The opening 231 partially exposes, for example, the upper surface of the first contact layer 220a of the light emitting portion 210. The passivation layer 230 may have a single-layer structure or a multi-layer structure. The passivation layer 230 may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, or various combinations thereof. A thickness of the passivation layer 230 may be about 5 nm or more and about 50 nm or less, for example, about 10 nm or more and about 30 nm or less. According to an embodiment, in an example case in which the light emitting portion 210 emits red light, the passivation layer 230 may include AlOₓN_{y}, and accordingly, the luminous efficiency of red light may be improved. According to an embodiment, in an example case in which the light emitting portion 210 emits blue light, the passivation layer 230 may include Ta₂O₅. As a result, the luminous efficiency of blue light may be improved.

The conductive reflective layer 240 may be provided the passivation layer 230. The conductive reflective layer 240 may include a conductive material. The conductive reflective layer 240 may include a conductive material having reflectivity. For example, the conductive material may include Al, Ti, Pt, Ag, Au, Pd, TiW, or various combinations thereof. According to an embodiment, the conductive reflective layer 240 may be provided on an entire area of the passivation layer 230. For example, the conductive reflective layer 240 may be provided on areas of the passivation layer 230 corresponding to the light emitting portion 210 and the electrode portion 260. For example, the conductive reflective layer 240 may cover the entire area of the passivation layer 230 including areas of the passivation layer 230 corresponding to the light emitting portion 210 and the electrode portion 260. The conductive reflective layer 240 is in contact with the first contact layer 220a of the light emitting portion 210 through the opening 231. Because the passivation layer 230 is disposed between the conductive reflective layer 240 and the second contact layer 220b of the electrode portion 260, the conductive reflective layer 240 does not contact the second contact layer 220b of the electrode portion 260. The conductive reflective layer 240 functions as an electrode of the plurality of light emitting portions 210, that is, as a p-electrode of the plurality of light emitting portions 210 in the embodiment. The conductive reflective layer 240 may be connected to a driving circuit of the display apparatus. For example, the conductive reflective layer 240 may be connected to a drain of a driving transistor.

An electrode pad (second electrode pad) 282 may be further provided on the conductive reflective layer 240. The second electrode pad 282 may be provided at a position corresponding to the electrode portion 260 on the conductive reflective layer 240. The second electrode pad 282 may include a conductive material. For example, the conductive material may include Al, Ti, Pt, Ag, Au, Pd, TiW, or various combinations thereof. In the embodiment, the second electrode pad 282 functions as a p-pad. The electrode pad 282 may be connected to the driving circuit of the display apparatus, for example, the drain of a driving transistor.

According to an embodiment, the light emitting device 1 may further include an electrode pad (first electrode pad) electrically connected to the first conductive semiconductor layer 201. The first electrode pad may be connected to a power line in the driving circuit of the display apparatus. In the display apparatus including the plurality of light emitting devices 1, the first electrode pad may be a common electrode.

The light emitting portion 210 includes the plurality of pores 270. The plurality of pores 270 are provided in the first conductive semiconductor layer 201. The plurality of pores 270 may be formed to extend in a transverse direction inward from the side surfaces of the first conductive semiconductor layer 201. In order to show shapes of the pore 270 viewed from various directions, the pores 270 are shown in FIG. 1 in a circular shape and a shape extending in the transverse direction. Among lights emitted from the active layer 202, light having an incident angle with respect to the surface 201a of the first conductive semiconductor layer 201 being more than a critical angle is emitted to the outside through the surface 201a of the first conductive semiconductor layer 201, and the remaining light is totally reflected on the surface 201a of the first conductive semiconductor layer 201. As described above, light trapped inside the light emitting device 1 by total internal reflection may be a factor that reduces the light extraction efficiency of the light emitting device 1. The plurality of pores 270 act as scattering centers of light emitted from the active layer 202. The totally reflected light is scattered by the plurality of pores 270 such that a traveling direction thereof changes, is incident again on the surface 201a of the first conductive semiconductor layer 201, and the light having the incident angle with respect to the surface 201a of the first conductive semiconductor layer 201 being more than the critical angle is emitted to the outside through the surface 201a of the first conductive semiconductor layer 201. As described above, the plurality of pores 270 scatter the light trapped inside the light emitting device 1 by total internal reflection, thereby changing the traveling direction of the light and allowing the light to be discharged from the light emitting device 1. As a result, the light emitting device 1 may have improved light extraction efficiency.

Light is generated by electron-hole recombination inside the active layer 202. In an example case in which the pore 270 exists within the active layer 202, a surface that causes surface recombination is provided at a boundary between a material forming the active layer 202 and the pore 270. Because the surface of a material generally has more crystal defects than the inside of the material, surface recombination is easier than inside recombination. Surface recombination is non-emission recombination, and may cause a decrease in the luminous efficiency of the active layer 202. Therefore, it is necessary to prevent the pore 270 from being formed in the active layer 202, and in the embodiment, the plurality of pores 270 may be formed to be spaced at least 100 nm apart from the active layer 202. For example, in FIG. 1, a separation distance 270D between the pore 270 closest to the active layer 202 and the active layer 202 may be 100 nm or more.

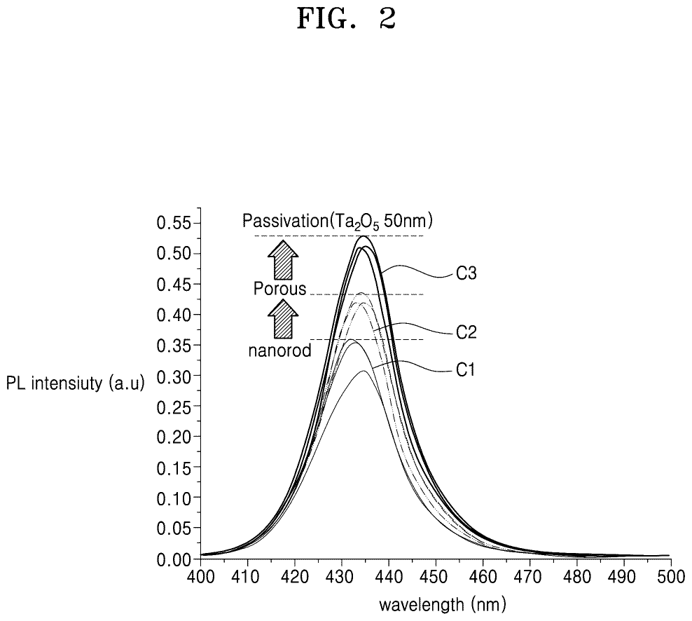

FIG. 2 is a graph showing a result of simulating photoluminescence (PL) characteristics of the light emitting device 1. In FIG. 2, graph C1 represents a case in which the plurality of pores 270 are not applied, graph C2 represents a case in which the plurality of pores 270 are applied, and graph C3 represents a case in which the plurality of pores 270 and the passivation layer 230 including Ta₂O₅ are applied. FIG. 2 shows that the case in which the plurality of pores 270 are applied (graph C2) has higher PL characteristics than the case in which the plurality of pores 270 are not applied (graph C1). Also, FIG. 2 shows that the case in which the passivation layer 230 including Ta₂O₅ is additionally applied has higher PL characteristics than the case in which the plurality of pores 270 are not applied (graph C1) and the case in which the plurality of pores 270 are applied (graph C2).

FIG. 3 is a schematic cross-sectional view of a light emitting device 1a according to an embodiment. The light emitting device 1a of the embodiment is a flip-chip type light emitting device. FIG. 3 shows that the light emitting device 1a is transferred to a carrier substrate 110 and flipped. The light emitting device 1a is attached to the carrier substrate 110 with an adhesive 112. The light emitting device 1a of the embodiment is different from the light emitting device 1 shown in FIG. 1 in that the electrode portion 260 is disabled (non-emitting). Hereinafter, components that are the same as those of the light emitting device 1 shown in FIG. 1 are denoted by the same reference numerals, and differences from the light emitting device 1 are mainly described. The description of the light emitting device 1 applies to the light emitting device 1a unless contradictory.

Referring to FIG. 3, a via hole 291 is formed through the epi structure 200 to expose the second contact layer 220b on the electrode portion 260. The via hole 291 penetrates the first conductive semiconductor layer 201, the active layer 202, and the second conductive semiconductor layer 203. The via hole 291 is formed from the surface 201a opposite to the active layer 202 among two surfaces of the first conductive semiconductor layer 201 in a stacking direction to the second contact layer 220b. By the via hole 291, an area of the epi structure 200 corresponding to the electrode portion 260 is disabled (non-emitting). As a result, the conductive reflective layer 240 that may function as a p-electrode may be exposed.

When forming the via hole 291 as described above, the second contact layer 220b may function as an etch stop layer. The second contact layer 220b may include a material, for example, ITO, having a large difference in an etch rate from the epi structure 200. ITO has a very low etch rate compared to GaN forming the epi structure 200. According to such a configuration, the risk of damage to the conductive reflective layer 240, which functions as the p-electrode, and the second electrode pad 282 in a process of forming the via hole 291 may be reduced.

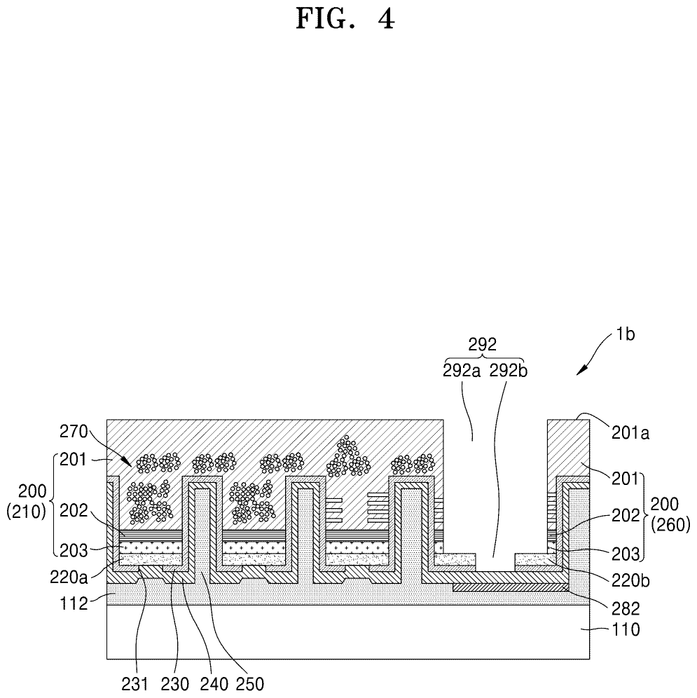

FIG. 4 is a schematic cross-sectional view of a light emitting device 1b according to an embodiment. The light emitting device 1b of this embodiment is a flip-chip type light emitting device. FIG. 4 shows that the light emitting device 1b is transferred and flipped to a carrier substrate 110. The light emitting device 1b is attached to the carrier substrate 110 with the adhesive 112. The light emitting device 1b of the embodiment is different from the light emitting device 1b shown in FIG. 3 in that a via hole 292 extends to the conductive reflective layer 240. Hereinafter, components that are the same as those of the light emitting device 1a shown in FIG. 3 are denoted by the same reference numerals, and differences from the light emitting device 1a are mainly described. Descriptions of the light emitting device 1 and the light emitting device 1a apply to the light emitting device 1b, unless contradictory.

Referring to FIG. 4, the via hole 292 is provided in the electrode portion 260. The via hole 292 penetrates the epi structure 200, the second contact layer 220b, and the passivation layer 230 to expose the conductive reflective layer 240. The via hole 292 may include a first via hole 292a penetrating the epi structure 200, and a second via hole 292b extending from the first via hole 292a to penetrate the second contact layer 220b and the passivation layer 230. A diameter of the second via hole 292b may be less than that of the first via hole 292a. The first via hole 292a is formed from the surface 201a opposite to the active layer 202 among two surfaces of the first conductive semiconductor layer 201 in a stacking direction to the second contact layer 220b. By the first via hole 292a, an area of the epi structure 200 corresponding to the electrode portion 260 is disabled (non-emitting). The via hole 292 may function as a connection hole for connecting a driving circuit of a display apparatus and a p-electrode. The driving circuit may be connected to the conductive reflective layer 240 through the via hole 292.

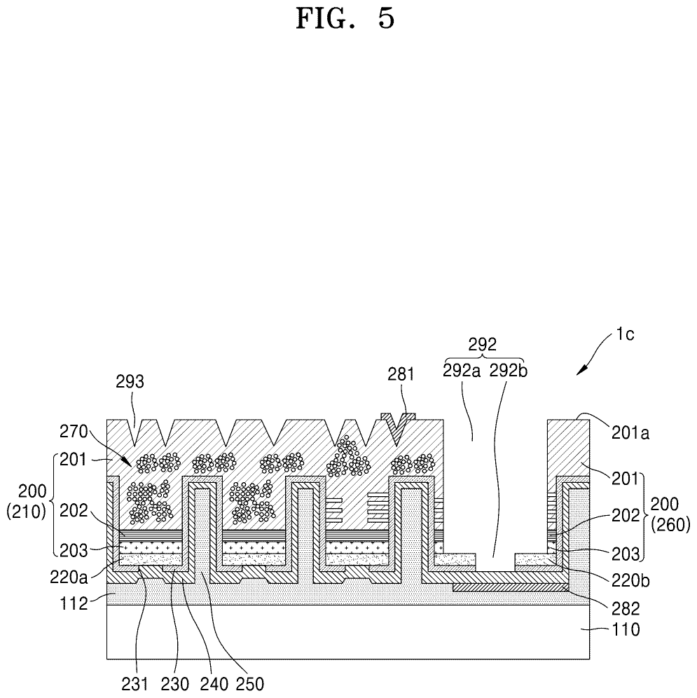

FIG. 5 is a schematic cross-sectional view of a light emitting device 1c according to an embodiment. The light emitting device 1c of the embodiment is a flip-chip type light emitting device. FIG. 5 shows that the light emitting device 1c is transferred and flipped to the carrier substrate 110. The light emitting device 1c is attached to the carrier substrate 110 with the adhesive 112. The light emitting device 1c of the embodiment is different from the light emitting device 1b shown in FIG. 4 in that the light emitting device 1c includes a scattering pattern 293. Hereinafter, components that are the same as those of the light emitting device 1b shown in FIG. 4 are denoted by the same reference numerals, and differences from the light emitting device 1b are mainly described. Descriptions of the light emitting device 1, the light emitting device 1a, and the light emitting device 1b apply to the light emitting device 1c, unless contradictory.

Referring to FIG. 5, the light emitting device 1c has the scattering pattern 293. The scattering pattern 293 is provided on the surface 201a of the first conductive semiconductor layer 201 opposite to the active layer 202. The scattering pattern 293 may be formed in an area of the surface 201a of the first conductive semiconductor layer 201 at least corresponding to the light emitting portion 210. The scattering pattern 293 may be, for example, an uneven pattern that may scatter light. In an example case in which light emitted from the active layer 202 is incident on the scattering pattern 293, the light is scattered by the scattering pattern 293. As a result, the light emitted from the light emitting device 1c has a uniform light intensity distribution. As described above, part of the light emitted from the active layer 202 is trapped inside the light emitting device 1c by total internal reflection. The scattering pattern 293 scatters the incident light and changes a traveling direction of the scattered light. As described above, the scattering pattern 293 scatters the light captured inside the light emitting device 1c by total internal reflection, thereby changing the traveling direction of the light and allowing the light to be discharged from the light emitting device 1c. As a result, a light emitting device 1c may have improved light extraction efficiency.

Referring again to FIG. 5, the light emitting device 1c may further include an electrode pad (first electrode pad) 281. The first electrode pad 281 may include a conductive material. For example, the conductive material may include Al, Ti, Pt, Ag, Au, Pd, TiW, or various combinations thereof. The first electrode pad 281 functions as an electrode of the plurality of light emitting portions 210, that is, as an n-electrode in the embodiment. The first electrode pad 281 may be connected to a power line in a driving circuit of a display apparatus. FIG. 5 shows one first electrode pad 281, but the light emitting device 1c may include two or more first electrode pads 281.

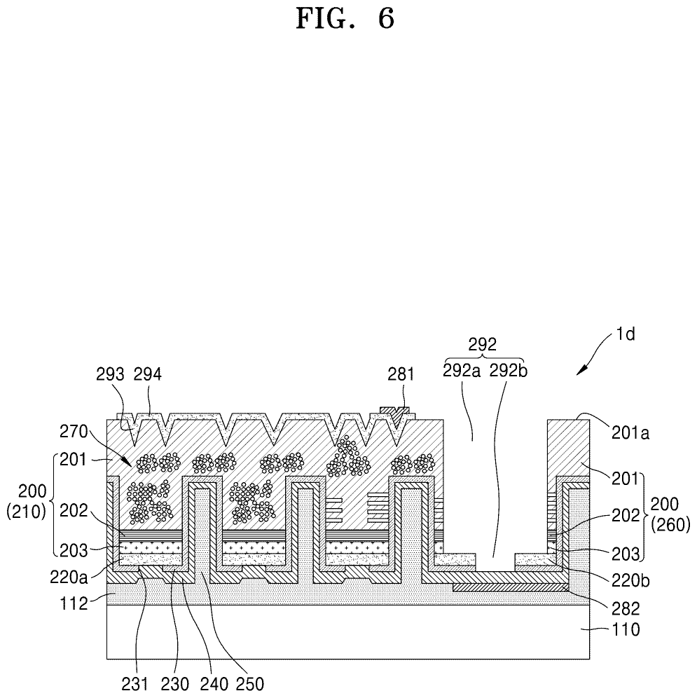

FIG. 6 is a schematic cross-sectional view of a light emitting device 1d according to an embodiment. The light emitting device 1d of the embodiment is a flip-chip type light emitting device. FIG. 6 shows that the light emitting device 1d is transferred and flipped to the carrier substrate 110. The light emitting device 1d is attached to the carrier substrate 110 with the adhesive 112. The light emitting device 1d of the embodiment is different from the light emitting device 1c shown in FIG. 5 in that the light emitting device 1d includes a transmission conductive layer 294. Hereinafter, components that are the same as those of the light emitting device 1c shown in FIG. 5 are denoted by the same reference numerals, and differences from the light emitting device 1c are mainly described. Descriptions of the light emitting device 1, the light emitting device 1a, the light emitting device 1b, and the light emitting device 1c apply to the light emitting device 1d, unless contradictory.

Referring to FIG. 6, the light emitting device 1d further includes the transmission conductive layer 294. The transmission conductive layer 294 may be provided the surface 201a of the first conductive semiconductor layer 201 opposite to the active layer 202. The transmission conductive layer 294 may cover the surface 201a of the first conductive semiconductor layer 201 opposite to the active layer 202. The transmission conductive layer 294 may be formed in an area of the surface 201a of the first conductive semiconductor layer 201 at least corresponding to the light emitting portion 210. In the embodiment, the scattering pattern 293 is provided on the surface 201a of the first conductive semiconductor layer 201, and the transmission conductive layer 294 may be provided on the scattering pattern 293. For example, the transmission conductive layer 294 may cover the scattering pattern 293. The transmission conductive layer 294 may include a transparent conductive material. The transmission conductive layer 294 may function, for example, as an n-electrode. The first electrode pad 281 may be further formed on the transmission conductive layer 294.

The transmission conductive layer 294 may function as a protective layer that protects the surface 201a or the scattering pattern 293 of the first conductive semiconductor layer 201 when forming the via hole 291 and/or the via hole 292. The transmission conductive layer 294 may include the same material as the second contact layer 220b, for example, ITO. In this case, the transmission conductive layer 294 may be referred to as a protective layer.

The transmission conductive layer 294 may function as a refractive index matching layer that increases light transmittance by compensating for the difference in refractive index between the light emitting device 1d and an external medium. The transmission conductive layer 294 may include a material having a refractive index between a refractive index of the epi structure 200 and a refractive index of an external medium, for example, air. For example, the transmission conductive layer 294 may include ITO.

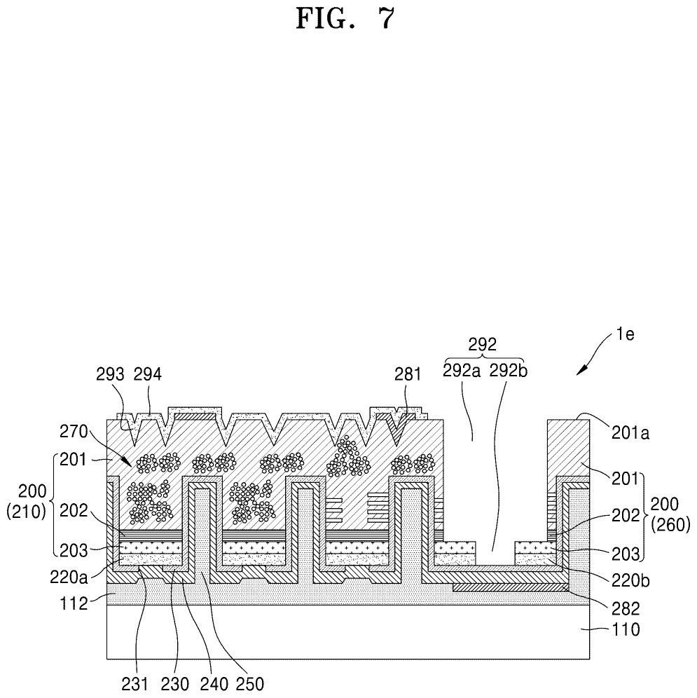

The order in which the transmission conductive layer 294 and the first electrode pad 281 are stacked is not limited. FIG. 7 is a schematic cross-sectional view of a light emitting device 1e according to an embodiment. As shown in FIG. 7, the first electrode pad 281 may be first formed on the surface 201a of the first conductive semiconductor layer 201, and the transmission conductive layer 294 may be provided on the surface 201a of the first conductive semiconductor layer 201 and the first electrode pad 281. For example, the transmission conductive layer 294 may cover the surface 201a of the first conductive semiconductor layer 201 and the first electrode pad 281.

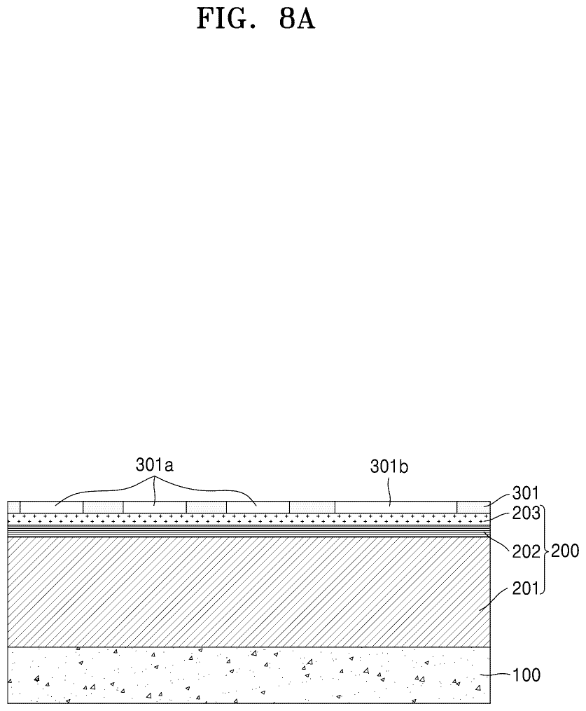

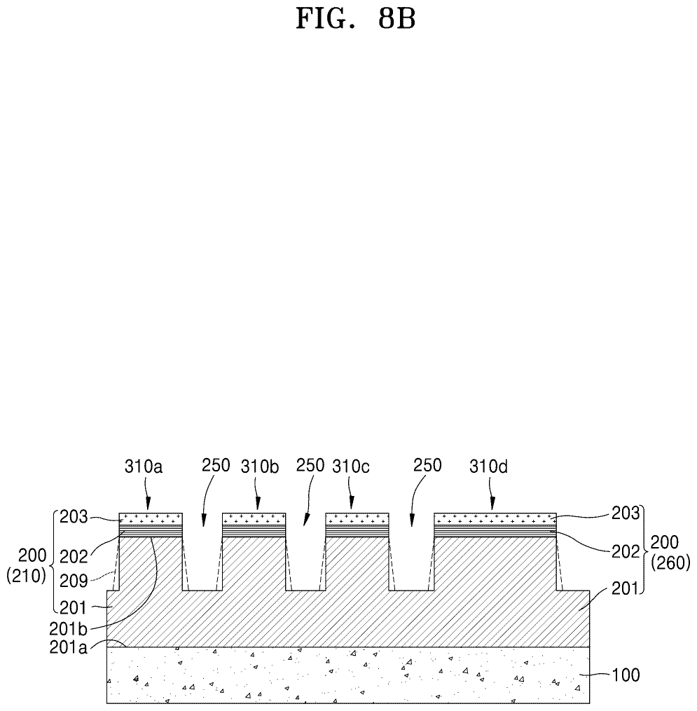

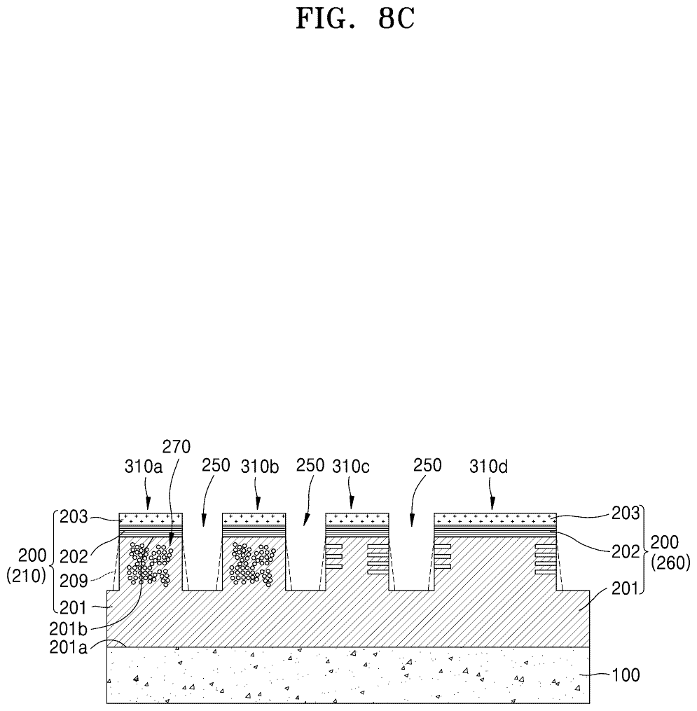

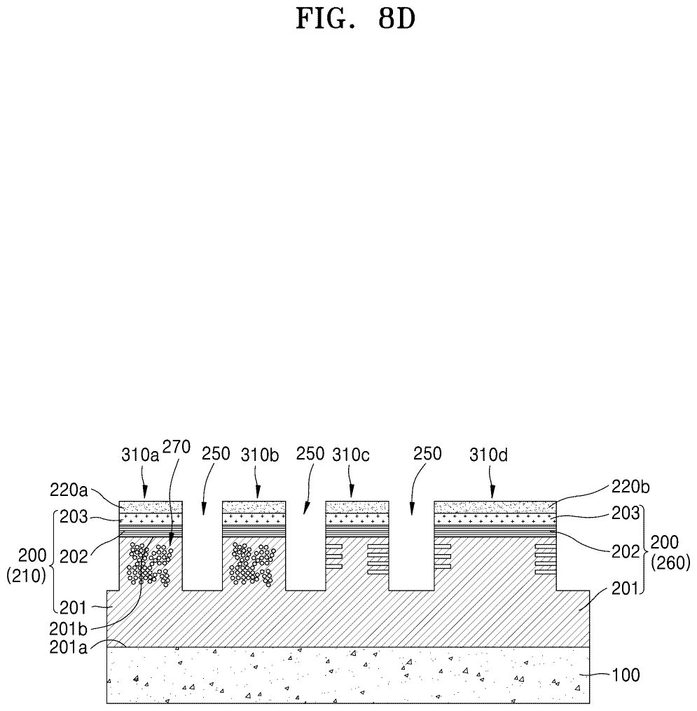

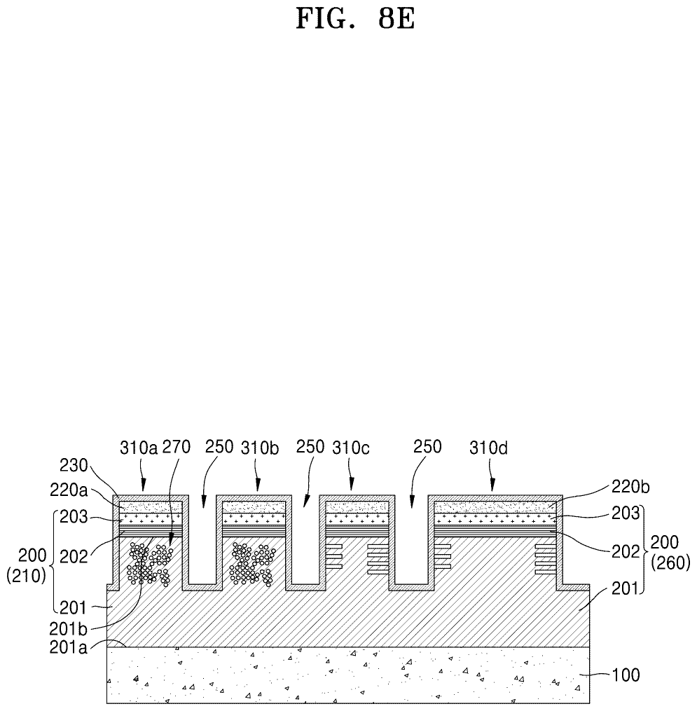

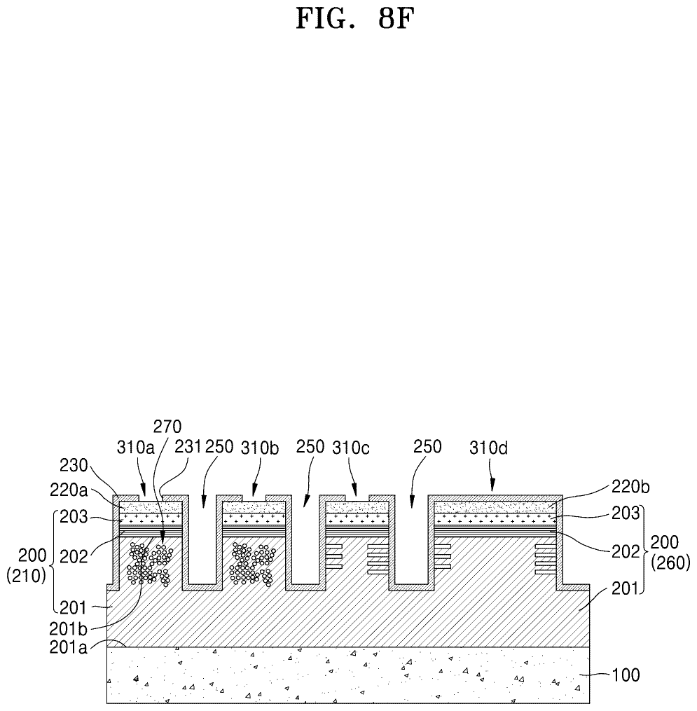

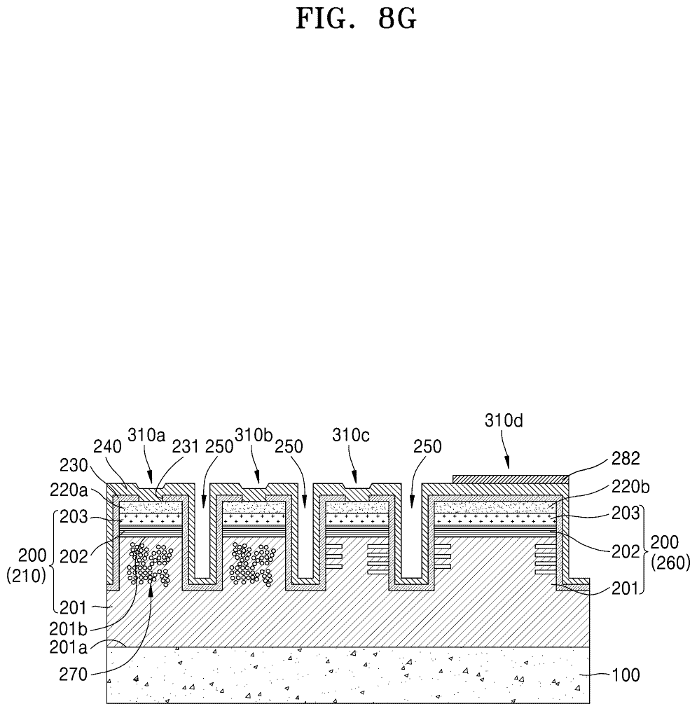

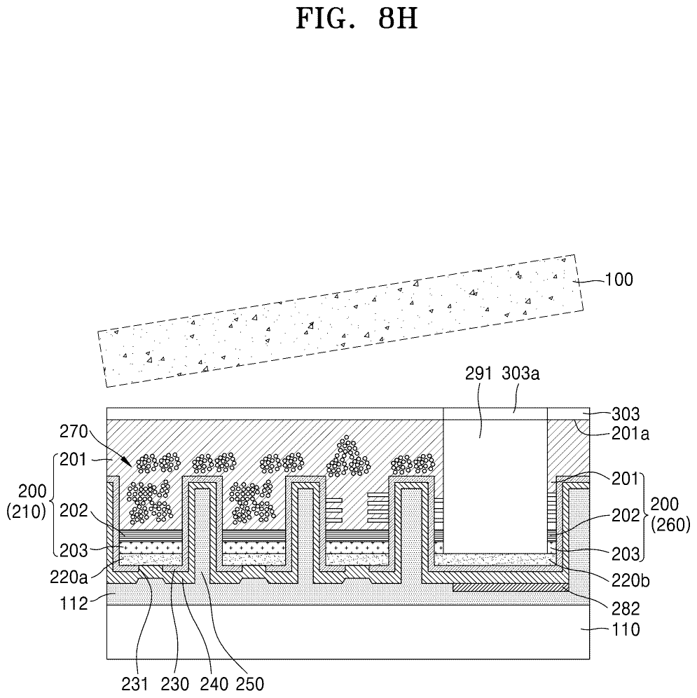

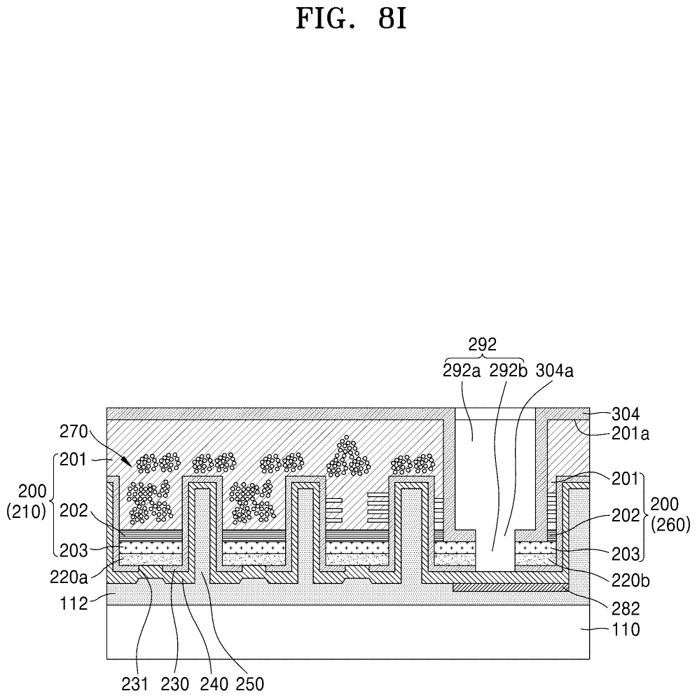

FIGS. 8A to 8I are diagrams showing a method of manufacturing a light emitting device according to an embodiment. Embodiments of the method of manufacturing the light emitting device will be described with reference to FIGS. 8A to 8I.

Referring to FIG. 8A, the epi structure 200 including the first conductive semiconductor layer 201, the active layer 202, and the second conductive semiconductor layer 203 is formed on the growth substrate 100.

The growth substrate 100 is, for example, a growth substrate for semiconductor single crystal growth, and may use a silicon (Si) substrate, a silicon carbide (SiC) substrate, a sapphire substrate, etc. Besides the above, a substrate including a material, suitable for the growth of the epi structure 200 to be formed on the substrate 100, for example, AlN, AlGaN, ZnO, GaAs, MgAl₂O₄, MgO, LiAlO₂, LiGaO₂, GaN, may be used. According to an embodiment, a buffer layer for epitaxial growth of the epi structure 200 may be provided on a surface of the substrate 100, and the epi structure 200 may be grown on the buffer layer. A silicon substrate is used as the substrate 100 in the embodiment.

The epi structure 200 may be formed by sequentially growing the first conductive semiconductor layer 201, the active layer 202, and the second conductive semiconductor layer 203 on the growth substrate 100. In an embodiment, a buffer layer may be grown on the growth substrate 100. For example, the buffer layer may be provided on the second conductive semiconductor layer 203. The epi structure 200 may include a Group III-V nitride semiconductor material. The Group III-V nitride semiconductor material may include, for example, GaN, InGaN, AlInGaN, AlGaInP, etc. In the embodiment, the epi structure 200 includes a GaN-based semiconductor material. The first conductive semiconductor layer 201 may be, for example, an n-GaN layer doped with n-type impurities. Si, Ge, Se, Te, etc. may be used as n-type impurities. The active layer 202 is a layer that emits light by electron-hole recombination, and may have a single quantum well or a multi quantum well structure as described above. For example, a quantum well layer and a barrier layer may be paired in the form of InGaN/GaN, InGaN/InGaN, InGaN/AlGaN, or InGaN/InAlGaN to form the quantum well structure, and a band gap energy may be controlled according to a composition ratio of indium (In) in a material layer including indium (In), and thus, an emission wavelength band may be adjusted. In the embodiment, the second conductive semiconductor layer 203 may be a p-GaN layer doped with p-type impurities. The epi structure 200 may be formed using HVPE, MBE, MOVPE, MOCVD, other known methods, or a combination thereof.

An operation of separating the light emitting portion 210 and the electrode portion 260 from each other is performed. The light emitting portion 210 and the electrode portion 260 may be separated from each other by forming the trench 250 in the epi structure 200 to expose the first conductive semiconductor layer 201. Referring to FIG. 8A, a mask pattern 301 is formed on an upper surface of the epi structure 200. An opening 301a corresponding to the light emitting portion 210 and an opening 301b corresponding to the electrode portion 260 are provided in the mask pattern 301. The mask pattern 301 may be formed as, for example, a SiO₂ hard mask.

The trench 250 may be formed by etching the epi structure 200 through the openings 301a and 301b, as shown in FIG. 8B. After etching is completed, the mask pattern 301 is removed. By the trench 250, the epi structure 200 may be divided into a plurality of mesa structures, for example, four mesa structures 310a, 310b, 310c, and 310d. The mesa structures 310a, 310b, and 310c may have the same height. The mesa structures 310a, 310b, and 310c may be the light emitting portion 210, and the mesa structure 310d may be the electrode portion 260.

According to an embodiment, etching may be performed using a dry etching process or a wet etching process. The dry etching process may use, for example, inductively coupled plasma (ICP). The wet etching process may be performed, for example, using a potassium hydroxide (KOH) solution or a tetramethyl ammonium hydroxide (TMAH) solution as an etchant. However, the disclosure is not limited thereto, and as such, the trench 250 may be formed in another manner.

According to an embodiment, sidewalls of the mesa structures 310a, 310b, 310c, and 310d may not be perpendicular to a surface of the substrate 100. As shown by a dashed line 209 in FIG. 8B, the sidewalls of the mesa structures 310a, 310b, 310c, and 310d may have a tapered shape with respect to the substrate 100. During a process of etching the epi structure 200, due to the difference in an etch rate between the surface 201b of the first conductive semiconductor layer 201 close to the mask pattern 301 and the surface 201a of the first conductive semiconductor layer 201 far from the mask pattern 301, the widths of the mesa structures 310a, 310b, 310c, and 310d may gradually increase from the surface 201b to the surface 201a. In other words, a width of the trench 250 may gradually decrease from the surface 201b toward the surface 201a. Inclinations of the sidewalls of the mesa structures 310a, 310b, 310c, and 310d may vary depending on the type of etching process and etching conditions. According to the wet etching process, the mesa structures 310a, 310b, 310c, and 310d with greater inclination angles of sidewalls may be obtained compared to the dry etching process.

As shown in FIG. 8C, the plurality of pores 270 are formed in the first conductive semiconductor layer 201. The plurality of pores 270 may be formed by etching the first conductive semiconductor layer 201 of the mesa structures 310a, 310b, 310c, and 310d in a transverse direction inward through the trench 250. For example, the plurality of pores 270 may be formed by a wet type electroetching process. Accordingly, in FIG. 8C, the plurality of pores 270 are shown in the form of holes and extending in the transverse direction from the sidewalls. The plurality of pores 270 may be formed at positions spaced apart from the active layer 202 by at least 100 nm. According to an embodiment, before forming the plurality of pores 270, side surfaces of the mesa structures 310a, 310b, 310c, and 310d, excluding an area where the plurality of pores 270 are to be formed, may be masked by a protective mask. The protective mask may be formed to an area of at least 100 nm from a lower surface of the active layer 202.

A process of forming the first contact layer 220a and the second contact layer 220b on the light emitting portion 210 and the electrode portion 260, respectively, is performed. After forming a deposition mask exposing the upper surfaces of the mesa structures 310a, 310b, 310c, and 310d in the state shown in FIG. 8C, a material capable of forming an ohmic contact with the second conductive semiconductor layer 203 is deposited on the exposed upper surfaces of the mesa structures 310a, 310b, 310c, and 310d. Then, as shown in FIG. 8D, the first contact layer 220a and the second contact layer 220b are formed on the light emitting portion 210 and the electrode portion 260, respectively. The first contact layer 220a and the second contact layer 220b may each include a conductive material. The conductive material may include Al, Ti, Pt, Ag, Au, Pd, TiW, or various combinations thereof. The first contact layer 220a and the second contact layer 220b may each include a transparent conductive material. The transparent conductive material may include ITO. The process of forming the first contact layer 220a and the second contact layer 220b is not limited. The first contact layer 220a and the second contact layer 220b may be formed, for example, using sputtering, atomic layer deposition (ALD), plasma enhanced atomic layer deposition (PEALD), chemical vapor deposition (CVD), plasma enhanced chemical vapor deposition (PECVD), physical vapor deposition (PVD), other known methods, or a combination thereof.

As is described below, the second contact layer 220b may include a material that may function as an etch stop layer with respect to a semiconductor material forming the epi structure 200, for example, GaN. For example, the second contact layer 220b may include ITO. The first contact layer 220a and the second contact layer 220b may include the same material, for example, ITO. As a result, the process may be simplified.

As shown in FIG. 8E, the passivation layer 230 may be provided on the side surfaces of the light emitting portion 210 and the electrode portion 260, and the first contact layer 220a and the second contact layer 220b. The passivation layer 230 may be provided on the side surfaces of the mesa structures 310a, 310b, 310c, and 310d exposed by the trench 250, the upper surface of the first conductive semiconductor layer 201 exposed by the trench 250, and the side surfaces and upper surfaces of the first contact layer 220a and the second contact layer 220b. For example, the passivation layer 230 covering the side surfaces of the light emitting portion 210 and the electrode portion 260, and the first contact layer 220a and the second contact layer 220b may be formed. The passivation layer 230 may cover the side surfaces of the mesa structures 310a, 310b, 310c, and 310d exposed by the trench 250, the upper surface of the first conductive semiconductor layer 201 exposed by the trench 250, and the side surfaces and upper surfaces of the first contact layer 220a and the second contact layer 220b. The passivation layer 230 may include a dielectric material. The dielectric material may include SiO₂, TiO₂, Si₃N₄, AlOₓ, AlOₓN_{y}, Ta₂O₅, TiN, AlN, ZrO₂, TiAlN, TiSiN, HfOₓ, or various combinations thereof. A thickness of the passivation layer 230 may be about 5 nm or more and about 50 nm or less, for example, about 10 nm or more and about 30 nm or less. The passivation layer 230 may have a single-layer structure or a multi-layer structure. The passivation layer 230 may include a material that may improve luminous efficiency according to an emission wavelength of the light emitting portion 210. In an example case in which light emitting portion 210 emits red light, the passivation layer 230 may include AlOₓN_{y}, and in an example case in which the light emitting portion 210 emits blue light, the passivation layer 230 may include Ta₂O₅. A process of forming the passivation layer 230 is not limited. For example, the passivation layer 230 may be formed using sputtering, ALD, PEALD, CVD, PECVD, PVD, other known methods, or a combination thereof.

Referring to FIG. 8F, the opening 231 exposing the first contact layer 220a is formed in the passivation layer 230. For example, an etch mask may be formed on the passivation layer 230. For example, the etch mask may cover the passivation layer 230. Etch holes are provided in areas corresponding to the mesa structures 310a, 310b, and 310c of the etch mask. The opening 231 is formed by etching the passivation layer 230 through the etch holes. The first contact layer 220a is partially exposed through the opening 231. The etch mask is removed.

As shown in FIG. 8G, the conductive reflective layer 240 may be provided on the passivation layer 230. For example, the conductive reflective layer 240 covering the passivation layer 230 is formed. The conductive reflective layer 240 may include a conductive material. The conductive reflective layer 240 may include a conductive material having reflectivity. For example, the conductive material may include Al, Ti, Pt, Ag, Au, Pd, TiW, or various combinations thereof. The conductive reflective layer 240 may have a single-layer structure or a multi-layer structure. A process of forming the conductive reflective layer 240 is not limited. For example, the conductive reflective layer 240 may be formed using sputtering, ALD, PEALD, CVD, PECVD, PVD, other known methods, or a combination thereof.

The conductive reflective layer 240 is in contact with the first contact layer 220a of the light emitting portion 210 through the opening 231. Because the passivation layer 230 is disposed between the conductive reflective layer 240 and the second contact layer 220b of the electrode portion 260, the conductive reflective layer 240 does not contact the second contact layer 220b of the electrode portion 260.

As shown in FIG. 8G, a process of forming the electrode pad (second electrode pad) 282 on the conductive reflective layer 240 may be further performed. The second electrode pad 282 may include a conductive material. For example, the conductive material may include Al, Ti, Pt, Ag, Au, Pd, TiW, or various combinations thereof. The second electrode pad 282 may be formed, for example, using sputtering, ALD, PEALD, CVD, PECVD, PVD, other known methods, or a combination thereof.

The light emitting device 1 shown in FIG. 1 may be manufactured through the above-described processes. Next, an embodiment of a method of manufacturing the light emitting device 1a shown in FIG. 3 is described.

After the process shown in FIGS. 8A to 8G is performed, a process result, that is, the epi structure 200, may be transferred to the carrier substrate 110. The carrier substrate 110 may be, for example, a silicon substrate. The epi structure 200 may be attached to the carrier substrate 110 with the adhesive 112. Then, the epi structure 200 is flipped. Then, as shown in FIG. 8H, in an example case in which the growth substrate 100 is separated, the surface 201a of the first conductive semiconductor layer 201 of the epi structure 200 is exposed. According to an embodiment, a process of etching the exposed surface of the first conductive semiconductor layer 201 of the epi structure 200 may be added. For example, the exposed surface of the first conductive semiconductor layer 201 of the epi structure 200 may be etched to, for example, about 2 μm.

Next, an etch mask 303 including an etch hole 303a is formed on the surface 201a of the first conductive semiconductor layer 201. The etch hole 303a is formed in an area corresponding to the electrode portion 260. The size of the etch hole 303a may be less than the size of the electrode portion 260. The etch mask 303 may include, for example, photoresist. The epi structure 200 of the electrode portion 260 is etched through the etch hole 303a. Etching may be performed using a dry etching process or a wet etching process. The dry etching process may use, for example, ICP. The wet etching process may be performed, for example, using a KOH solution or a TMAH solution as an etchant. In the embodiment, the etching process is performed by the wet etching process using the TMAH solution as an etchant. In the etching process, the second contact layer 220b including ITO functions as an etch stop layer. As a result, the via hole 291 penetrating the first conductive semiconductor layer 201, the active layer 202, and the second conductive semiconductor layer 203 of the electrode portion 260 may be formed, and the electrode portion 260 may be disabled (non-emitting). The etch mask 303 is removed.

In an example case in which an etching process error is ±5%, and a GaN layer with a thickness of about 8 μm is etched, the maximum etch error of the GaN layer is about 800 nm. Such a large etch error may damage the conductive reflective film 240 which is used as a p-electrode. According to experiments, an etch rate of GaN is about 8.2 nm/s, which is about 19.5 times an etch rate of ITO, which is about 0.42 nm/s. Mathematically, an ITO layer with a thickness of about 100 nm may correspond to a GaN layer with a thickness of about 2 μm in terms of etch thickness, and the second contact layer 220b including ITO may function as an excellent etch stop layer. By forming the second contact layer 220b with ITO of an appropriate thickness in consideration of the etching process error, damage to the conductive reflective layer 240 that is the p-electrode may be prevented in the etching process for forming the via hole 291 in the electrode portion 260. As described above, the light emitting device 1a shown in FIG. 3 including the via hole 291 may be manufactured.

Next, an embodiment of a method of manufacturing the light emitting device 1b shown in FIG. 4 including the via hole 292 is described.

By the process shown in FIG. 8H, the first via hole 292a penetrating the first conductive semiconductor layer 201, the active layer 202, and the second conductive semiconductor layer 203 of the electrode portion 260 may be formed. Then, as shown in FIG. 8I, an etch mask 304 including an etch hole 304a is formed on the second contact layer 220b. The etch mask 304 may include photoresist, for example. The second via hole 292b is formed by etching the second contact layer 220b and the passivation layer 230 through the etch hole 304a. Etching may be performed using a dry etching process or a wet etching process. As a result, the via hole 292 including the first via hole 292a penetrating the epi structure 200 of the electrode portion 260 and the second via hole 292b penetrating the second contact layer 220b and the passivation layer 230 to exposing the conductive reflective layer 240 may be formed. The etch mask 304 is removed.

As shown in FIGS. 5, 6, and 7, the scattering pattern 293 may be provided on the surface 201a of the first conductive semiconductor layer 201. A first electrode pad 281 may be provided on the surface 201a of the first conductive semiconductor layer 201. The transmission conductive layer 294 may be provided on a surface of the first conductive semiconductor layer 201.

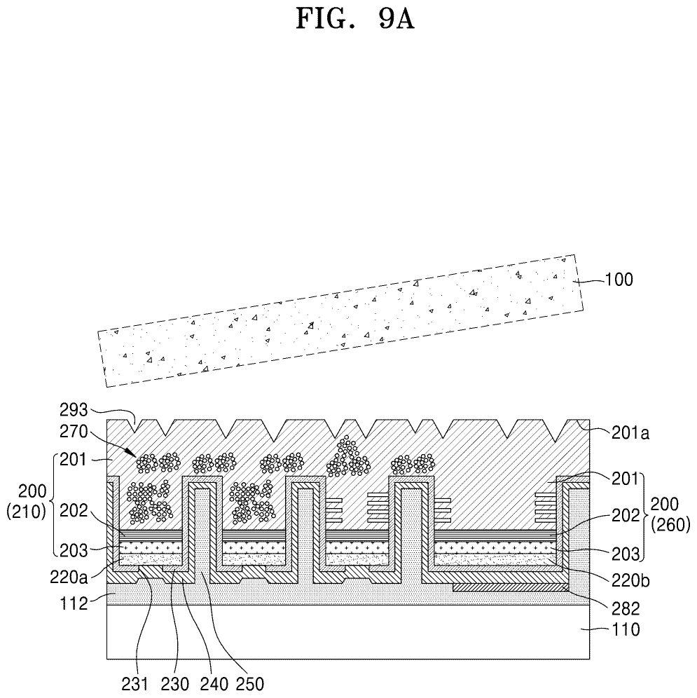

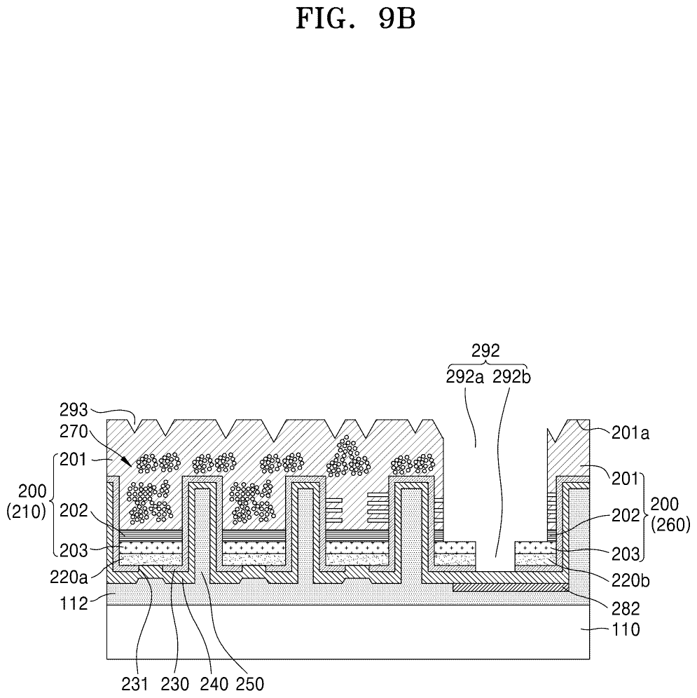

FIGS. 9A and 9B are diagrams showing an operation of forming the scattering pattern 293, as an embodiment of a light emitting device manufacturing method. First, processes of FIGS. 8A to 8G are performed. Then, as shown in FIG. 9A, a process result, that is, the epi structure 200, may be transferred to the carrier substrate 110. The carrier substrate 110 may be, for example, a silicon substrate. The epi structure 200 may be attached to the carrier substrate 110 with the adhesive 112. Then, the epi structure 200 is flipped. Then, when the growth substrate 100 is separated, the surface 201a of the first conductive semiconductor layer 201 of the epi structure 200 is exposed. According to an embodiment, a process of etching the exposed surface of the first conductive semiconductor layer 201 of the epi structure 200 may be added. For example, the exposed surface of the first conductive semiconductor layer 201 of the epi structure 200 may be etched to, for example, about 2 μm.

Next, the scattering pattern 293 may be formed on the surface 201a of the first conductive semiconductor layer 201, as shown in FIG. 9A, by etching the surface 201a of the first conductive semiconductor layer 201. Etching may be performed, for example, using a wet etching process using a TMAH solution as an etchant. Next, the via hole 291 or the via hole 292 may be formed as shown in FIG. 9B by performing the processes of FIGS. 8H and 8I.

According to an embodiment, the scattering pattern 293 may be formed on the surface 201a of the first conductive semiconductor layer 201 by performing a process of FIG. 9A after performing the process of FIGS. 8A to 8I. In this case, before an etching process for forming the scattering pattern 293 is performed, a protective layer blocking the via hole 292 to prevent the conductive reflective layer 240 from being damaged through the via hole 292 may be provided. After forming the scattering pattern 293, the protective layer is removed.

Next, in the state shown in FIG. 9B, a process of forming the first electrode pad 281 on the surface 201a of the first conductive semiconductor layer 201 may be performed, as shown in FIG. 5. The first electrode pad 281 may include a conductive material. For example, the conductive material may include Al, Ti, Pt, Ag, Au, Pd, TiW, or various combinations thereof. The first electrode pad 281 may be formed, for example, using sputtering, ALD, PEALD, CVD, PECVD, PVD, other known methods, or a combination thereof. A plurality of first electrode pads 281 may be formed. As a result, the light emitting device 1c shown in FIG. 5 may be manufactured.

Before forming the first electrode pad 281, that is, in the state shown in FIG. 9B, a process of forming the transmission conductive layer 294 on the surface 201a of the first conductive semiconductor layer 201 may be performed, as shown in FIG. 6. The transmission conductive layer 294 may include a transparent conductive material. For example, the transparent conductive material may include ITO. The transmission conductive layer 294 may be formed in an area of the surface 201a of the first conductive semiconductor layer 201 at least corresponding to the light emitting portion 210. According to an embodiment, the transmission conductive layer 294 may be provided on the scattering pattern 293. For example, the transmission conductive layer 294 may cover the scattering pattern 293. The transmission conductive layer 294 may be formed, for example, using ALD. Then, the first electrode pad 281 may be formed on the transmission conductive layer 294. As a result, the light emitting device 1d shown in FIG. 6 may be manufactured.

In the state shown in FIG. 9B, the first electrode pad 281 may be first formed on the surface 201a of the first conductive semiconductor layer 201 as shown in FIG. 5, and then, as shown in FIG. 7, the transmission conductive layer 294 may be provided on the surface 201a of the first conductive semiconductor layer 201 and the first electrode pad 281. For example, the transmission conductive layer 294 covering the surface 201a of the first conductive semiconductor layer 201 and the first electrode pad 281 may be formed. By this, the light emitting device 1e shown in FIG. 7 may be manufactured.

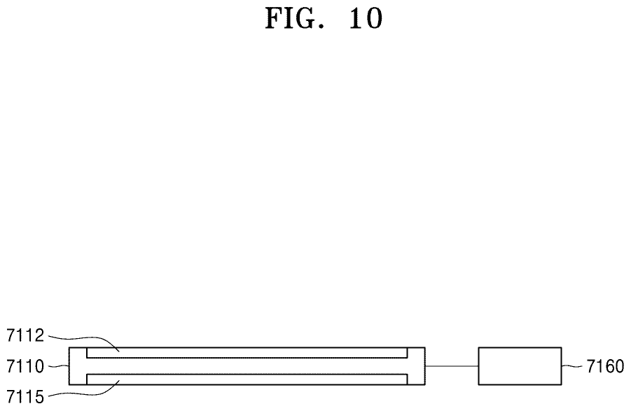

FIG. 10 is a schematic diagram of a display apparatus according to an embodiment. Referring to FIG. 10, the display apparatus may include a display panel 7110 and a controller 7160. The display panel 7110 may include a light emitting structure 7112 and a driving circuit 7115. The driving circuit 7115 may control an operation of the light emitting structure 7112. For example, the driving circuit 7115 may switch the light emitting structure 7112 on or off. The light emitting structure 7112 may include a plurality of light emitting devices described with reference to FIGS. 1 to 7 above. The plurality of light emitting devices may be arranged, for example, in a two-dimensional array. The driving circuit 7115 may include a plurality of switching devices individually switching on-off the plurality of light emitting devices. The controller 7160 may input on-off switching signals of the plurality of light emitting devices to the driving circuit 7115 according to an image signal.

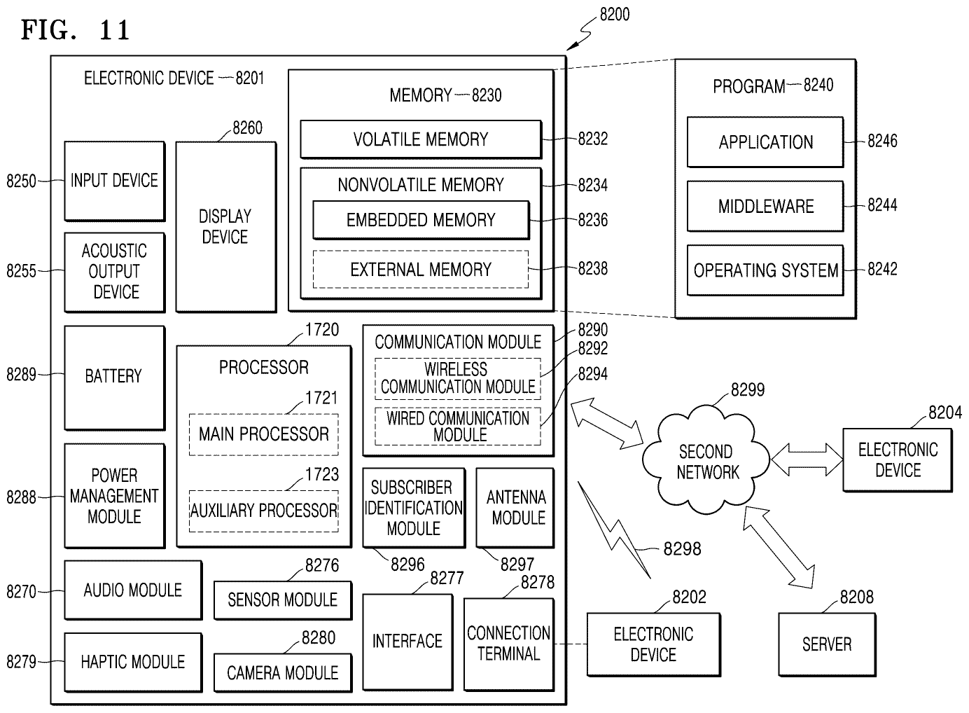

FIG. 11 is a block diagram of an electronic device 8201 including a display according to an embodiment. Referring to FIG. 11, the electronic device 8201 may be provided in a network environment 8200. In the network environment 8200, the electronic device 8201 may communicate with another electronic device 8202 through a first network 8298 (such as a short-range wireless communication network, and the like), or communicate with another electronic device 8204 and/or a server 8208 through a second network 8299 (such as a remote wireless communication network). The electronic device 8201 may communicate with the electronic device 8204 through the server 8208. The electronic device 8201 may include a processor 8220, a memory 8230, an input device 8250, an audio output device 8255, a display apparatus 8260, an audio module 8270, a sensor module 8276, and an interface 8277, a haptic module 8279, a camera module 8280, a power management module 8288, a battery 8289, a communication module 8290, a subscriber identification module 8296, and/or an antenna module 8297. In the electronic device 8201, some of these components may be omitted or other components may be added. Some of these components may be implemented as one integrated circuit. For example, the sensor module 8276 (fingerprint sensor, iris sensor, illuminance sensor, etc.) may be implemented by being embedded in the display apparatus 8260 (display, etc.)

The processor 8220 may execute software (the program 8240, etc.) to control one or a plurality of other components (such as hardware, software components, etc.) of the electronic device 8201 connected to the processor 8220, and perform various data processing or operations. As part of data processing or operation, the processor 8220 may load commands and/or data received from other components (the sensor module 8276, the communication module 8290, etc.) into the volatile memory 8232, process commands and/or data stored in the volatile memory 8232, and store result data in the nonvolatile memory 8234. The processor 8220 may include a main processor 8221 (such as a central processing unit, an application processor, etc.) and a secondary processor 8223 (such as a graphics processing unit, an image signal processor, a sensor hub processor, a communication processor, etc.) that may be operated independently or together. The secondary processor 8223 may use less power than the main processor 8221 and may perform specialized functions.

The secondary processor 8223 may control functions and/or states related to some of the components of the electronic device 8202 (such as the display apparatus 8260, the sensor module 8276, the communication module 8290, etc.) instead of the main processor 8221 while the main processor 8221 is in an inactive state (sleep state), or with the main processor 8221 while the main processor 8221 is in an active state (application execution state). The secondary processor 8223 (such as an image signal processor, a communication processor, etc.) may be implemented as part of other functionally related components (such as the camera module 8280, the communication module 8290, etc.)

The memory 8230 may store various data required by components of the electronic device 8201 (such as the processor 8220, the sensor module 8276, etc.) The data may include, for example, software (such as the program 8240, etc.) and input data and/or output data for commands related thereto. The memory 8230 may include a volatile memory 8232 and/or a nonvolatile memory 8234.

The program 8240 may be stored as software in the memory 8230 and may include an operating system 8242, a middleware 8244, and/or an application 8246.

The input device 8250 may receive commands and/or data to be used for components (such as the processor 8220, etc.) of the electronic device 8201 from outside (a user) of the electronic device 8201. The input device 8250 may include a remote controller, a microphone, a mouse, a keyboard, and/or a digital pen (such as a stylus pen).

The audio output device 8255 may output an audio signal to the outside of the electronic device 8201. The audio output device 8255 may include a speaker and/or a receiver. The speaker may be used for general purposes such as multimedia playback or recording playback, and the receiver may be used to receive incoming calls. The receiver may be combined as a part of the speaker or may be implemented as an independent separate device.

The display apparatus 8260 may visually provide information to the outside of the electronic device 8201. The display apparatus 8260 may include the display, a hologram device, or a projector and a control circuit for controlling the device. The display apparatus 8260 may include the display described with reference to FIG. 10. The display apparatus 8260 may include a touch circuit set to sense a touch, and/or a sensor circuit (such as a pressure sensor) set to measure the strength of a force generated by the touch.

The audio module 8270 may convert sound into an electrical signal, or conversely, may convert an electrical signal into sound. The audio module 8270 may acquire sound through the input device 8250 or output sound through speakers and/or headphones of the audio output device 8255, and/or another electronic device (such as the electronic device 8102) directly or wirelessly connected to electronic device 8201.

The sensor module 8276 may detect an operating state (such as power, temperature, and the like) of the electronic device 8201 or an external environmental state (such as a user state, and the like), and generate an electrical signal and/or data value corresponding to the detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more specified protocols that may be used for the electronic device 8201 to connect directly or wirelessly with another electronic device (such as the electronic device 8102). The interface 8277 may include a High Definition Multimedia Interface (HDMI), a Universal Serial Bus (USB) interface, an SD card interface, and/or an audio interface.

The connection terminal 8278 may include a connector through which the electronic device 8201 may be physically connected to another electronic device (such as the electronic device 8102). The connection terminal 8278 may include an HDMI connector, a USB connector, an SD card connector, and/or an audio connector (such as a headphone connector).

The haptic module 8279 may convert an electrical signal into a mechanical stimulus (such as vibration, movement, etc.) or an electrical stimulus that a user may perceive through a tactile or motor sense. The haptic module 8279 may include a motor, a piezoelectric element, and/or an electrical stimulation device.

The camera module 8280 may capture a still image and a video. The camera module 8280 may include a lens assembly including one or more lenses, image sensors, image signal processors, and/or flashes. The lens assembly included in the camera module 8280 may collect light emitted from a subject that is a target of image capturing.

The power management module 8288 may manage power supplied to the electronic device 8201. The power management module 8388 may be implemented as a part of a Power Management Integrated Circuit (PMIC).

The battery 8289 may supply power to components of the electronic device 8201. The battery 8289 may include a non-rechargeable primary cell, a rechargeable secondary cell, and/or a fuel cell.

The communication module 8290 may support establishing a direct (wired) communication channel and/or a wireless communication channel, and performing communication through the established communication channel between the electronic device 8201 and other electronic devices (such as the electronic device 8102, the electronic device 8104, the server 8108, and the like). The communication module 8290 may include one or more communication processors that operate independently of the processor 8220 (such as an application processor) and support direct communication and/or wireless communication. The communication module 8290 may include a wireless communication module 8292 (such as a cellular communication module, a short-range wireless communication module, a Global Navigation Satellite System (GNSS) communication module, and the like) and/or a wired communication module 8294 (such as a local area network (LAN) communication module, a power line communication module, and the like). Among these communication modules, a corresponding communication module may communicate with other electronic devices through a first network 8298 (a short-range communication network such as Bluetooth, WiFi Direct, or Infrared Data Association (IrDA)) or a second network 8299 (a cellular network, the Internet, or a telecommunication network such as a computer network (such as LAN, WAN, and the like)). These various types of communication modules may be integrated into one component (such as a single chip, and the like), or may be implemented as a plurality of separate components (a plurality of chips). The wireless communication module 8292 may check and authenticate the electronic device 8201 in a communication network such as the first network 8298 and/or the second network 8299 using the subscriber information (such as international mobile subscriber identifier (IMSI), etc.) stored in the subscriber identification module 8296.

The antenna module 8297 may transmit signals and/or power to the outside (such as other electronic devices) or receive signals and/or power from the outside. The antenna may include a radiator made of a conductive pattern formed on a substrate (such as PCB, etc.) The antenna module 8297 may include one or a plurality of antennas. In an example case in which multiple antennas are included, an antenna suitable for a communication method used in a communication network such as the first network 8298 and/or the second network 8299 may be selected from the plurality of antennas by the communication module 8290. Signals and/or power may be transmitted or received between the communication module 8290 and another electronic device through the selected antenna. In addition to the antenna, other components (such as RFIC) may be included as part of the antenna module 8297.

Some of the components are connected to each other and may exchange signals (such as commands, data, and the like) through communication method between peripheral devices (such as bus, General Purpose Input and Output (GPIO), Serial Peripheral Interface (SPI), Mobile Industry Processor Interface (MIPI), and the like).

The command or data may be transmitted or received between the electronic device 8201 and the external electronic device 8204 through the server 8108 connected to the second network 8299. The other electronic devices 8202 and 8204 may be the same or different types of devices as or from the electronic device 8201. All or some of the operations executed by the electronic device 8201 may be executed by one or more of the other electronic devices 8202, 8204, and 8208. In an example case in which the electronic device 8201 needs to perform a certain function or service, instead of executing the function or service itself, the electronic device 8201 may request one or more other electronic devices to perform the function or part or all of the service. One or more other electronic devices that receive the request may execute an additional function or service related to the request, and transmit a result of the execution to the electronic device 8201. To this end, cloud computing, distributed computing, and/or client-server computing technology may be used.

The electronic device 8201 described above may be applied to various devices. According to functions of devices, various components of the electronic device 8201 described above may be appropriately modified, and components appropriate for performing the functions of the devices may be added. Application examples of the electronic device 8201 are described below.

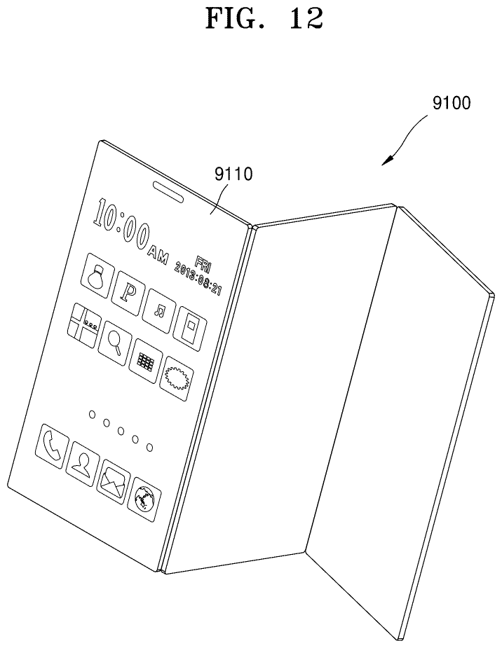

FIG. 12 illustrates an embodiment of a mobile device 9100 as an application example of an electronic device. The mobile device 9100 may include a display apparatus 9110. The display apparatus 9110 may include the display apparatus described with reference to FIG. 10. The display apparatus 9110 may have a foldable structure, for example, a multi-foldable structure.

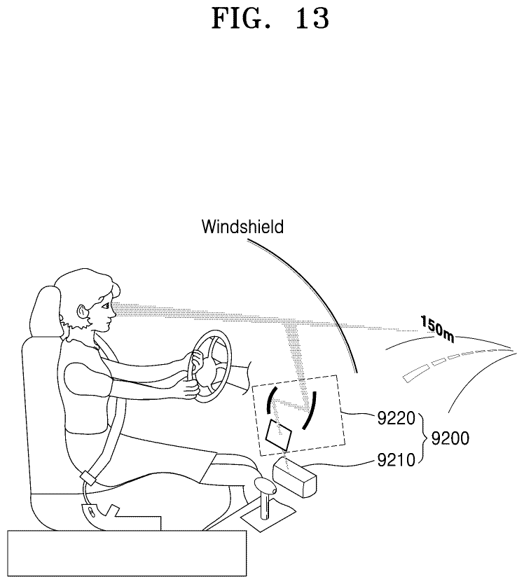

FIG. 13 illustrates an embodiment of a vehicle head-up display apparatus 9200 as an application example of an electronic device. The vehicle head-up display apparatus 9200 may include a display 9210 provided in an area of a vehicle, and a light path changing member 9220 that converts an optical path so that a driver may see the image generated on the display 9210. The display 9210 may include the display apparatus described with reference to FIG. 10.

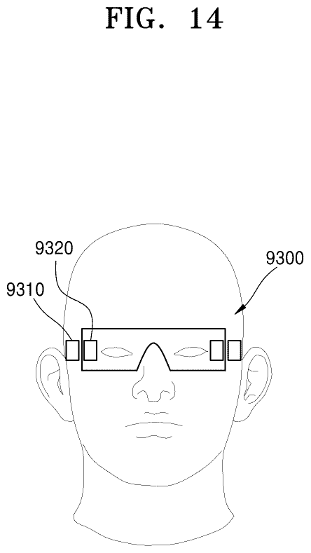

FIG. 14 illustrates an embodiment of augmented reality glasses 9300 or virtual reality glasses 9300 as an application example of an electronic device. The augmented reality glasses (virtual reality glasses) 9300 may include a projection system 9310 that forms an image, and an element 9320 that guides the image from the projection system 9310 into the user's eye. The projection system 9310 may include the display apparatus described with reference to FIG. 10.

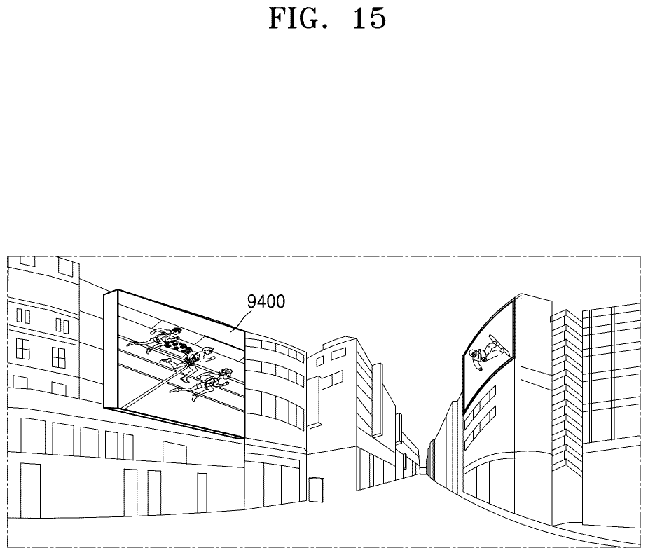

FIG. 15 illustrates an embodiment of a signage 9400 as an application example of an electronic device. The signage 9400 may include the display apparatus described with reference to FIG. 10. The signage 9400 may be used for outdoor advertisement using a digital information display, and may control advertisement contents and the like through a communication network. The signage 9400 may be implemented, for example, through the electronic device described with reference to FIG. 11.

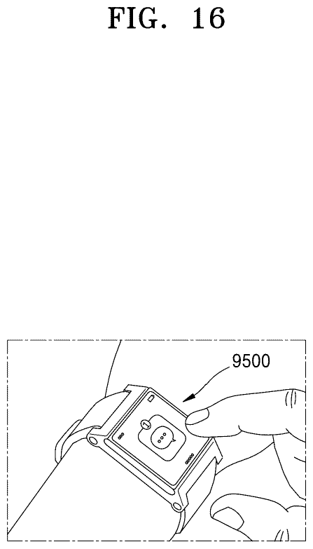

FIG. 16 illustrates an embodiment of a wearable display 9500 as an application example of an electronic device. The wearable display 9500 may include the display apparatus described with reference to FIG. 11. The wearable display 9500 may be implemented through the electronic device described with reference to FIG. 11.

The light emitting device according to the embodiment or the display apparatus including the light emitting device may also be applied to various products such as a rollable TV and a stretchable display.

According to some embodiments, the light emitting device with improved luminous efficiency and the display apparatus employing the light emitting device may be implemented.

According to some embodiments, the risk of damaging the electrode may be reduced in the process of non-emitting the electrode portion and exposing the electrode.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light emitting device comprising:
a light emitting portion and an electrode portion, each of the light emitting portion and the electrode portion comprising:
an epi structure comprising:
a first conductive semiconductor layer comprising a plurality of pores,
an active layer, and
a second conductive semiconductor layer,
a trench between the light emitting portion, and the electrode portion to expose the first conductive semiconductor layer;
a first contact layer on the second conductive semiconductor layer of the light emitting portion;
a second contact layer on the second conductive semiconductor layer of the electrode portion;
a passivation layer provided on one or more side surfaces of the light emitting portion, and the electrode portion, and on the first contact layer and the second contact layer, the passivation layer comprising an opening exposing the first contact layer of the light emitting portion; and
a conductive reflective layer provided on the passivation layer and contacting the first contact layer of the light emitting portion through the opening.

2. The light emitting device of claim 1, wherein the plurality of pores are spaced apart from the active layer by at least 100 nm.

3. The light emitting device of claim 1, further comprising:
an electrode pad provided on the conductive reflective layer at a position corresponding to the electrode portion.

4. The light emitting device of claim 1, wherein the second contact layer comprises Indium Tin Oxide (ITO).

5. The light emitting device of claim 4, wherein a via hole penetrating the epi structure is formed on the electrode portion to expose the second contact layer.

6. The light emitting device of claim 5, wherein the via hole penetrates the second contact layer and the passivation layer to expose the conductive reflective layer.

7. The light emitting device of claim 1, further comprising:
an electrode pad provided on a surface of the first conductive semiconductor layer opposite to the active layer.

8. The light emitting device of claim 1, further comprising:
a transmission conductive layer provided on a surface of the first conductive semiconductor layer opposite to the active layer.

9. The light emitting device of claim 8, wherein the transmission conductive layer comprises Indium Tin Oxide (ITO).

10. The light emitting device of claim 1, further comprising:
a scattering pattern provided on a surface of the first conductive semiconductor layer opposite to the active layer.

11. A method of manufacturing a light emitting device, the method comprising:
forming an epi structure comprising a first conductive semiconductor layer, an active layer, and a second conductive semiconductor layer on a growth substrate;
separating a light emitting portion and an electrode portion from each other by forming a trench in the epi structure to expose the first conductive semiconductor layer;
forming a first contact layer on the second conductive semiconductor layer of the light emitting portion, and forming a second contact layer on the second conductive semiconductor layer of the electrode portion;
forming a plurality of pores in the first conductive semiconductor layer;
forming a passivation layer on one or more side surfaces of the light emitting portion and the electrode portion, and on the first contact layer and the second contact layer;
forming an opening in the passivation layer to expose the first contact layer of the light emitting portion; and
forming a conductive reflective layer covering the passivation layer and contacting the first contact layer of the light emitting portion through the opening.

12. The method of claim 11, wherein the plurality of pores are spaced apart from the active layer by at least 100 nm.

13. The method of claim 11, further comprising:
forming an electrode pad on the conductive reflective layer at a position corresponding to the electrode portion.

14. The method of claim 11, wherein the first contact layer and the second contact layer each comprise Indium Tin Oxide (ITO).

15. The method of claim 11, further comprising:
transferring the epi structure onto a carrier substrate; and
forming a via hole penetrating the first conductive semiconductor layer, the active layer, and the second conductive semiconductor layer of the electrode portion by using the second contact layer as an etch stop layer.

16. The method of claim 15, wherein the via hole penetrates the second contact layer and the passivation layer to expose the conductive reflective layer.

17. The method of claim 11, further comprising:
transferring the epi structure onto a carrier substrate; and
forming an electrode pad on a surface of the first conductive semiconductor layer.

18. The method of claim 11, further comprising:
forming a scattering pattern on the surface of the first conductive semiconductor layer.

19. The method of claim 11, further comprising:
forming a transmission conductive layer on the surface of the first conductive semiconductor layer.

20. A display apparatus comprising:
a display panel comprising a plurality of light emitting devices, and a driving circuit configured to switch the plurality of light emitting devices on or off; and
a controller configured to input switching signals of the plurality of light emitting devices to the driving circuit according to an image signal,
wherein each of the plurality of light emitting devices comprises:
a light emitting portion and an electrode portion, each of the light emitting portion and the electrode portion comprising:
an epi structure comprising:
a first conductive semiconductor layer comprising a plurality of pores,
an active layer, and
a second conductive semiconductor layer,
a trench between the light emitting portion, and the electrode portion;
a first contact layer on the second conductive semiconductor layer of the light emitting portion;
a second contact layer on the second conductive semiconductor layer of the electrode portion;
a passivation layer provided on one or more side surfaces of the light emitting portion, and the electrode portion, and on the first contact layer and the second contact layer, the passivation layer comprising an opening exposing the first contact layer of the light emitting portion; and
a conductive reflective layer provided on the passivation layer and contacting the first contact layer of the light emitting portion through the opening.
